(19) United States
(12) Patent Application Publication
(10) Pub. No.: US 2010/0083491 A1
(43) Pub. Date: Apr. 8, 2010

(54) ELECTONIC COMPONENT MOUNTING APPARATUS

(75) Inventor: Tsutomu Hiraki, Saga (JP)

Correspondence Address: PEARNE & GORDON LLP, 1801 EAST 9TH STREET, SUITE 1200, CLEVELAND, OH, 44114-3108, US

(73) Assignee: PANASONIC CORPORATION, Osaka (JP)

(21) Appl. No.: 12/570,050

(22) Filed: Sep. 30, 2009

(30) Foreign Application Priority Data
Oct. 6, 2008 (JP) 2008-259234

(51) Int. Cl. H05K 3/30

(52) U.S. Cl. 29/832

(57) ABSTRACT

A paste storage portion 10 is made up of a first storage portion 24 and a second storage portion 25 which are arranged concentrically, and a first transfer position 31 where a transfer head 11 transfers a paste adhesive stored in the first storage portion, a second transfer position 32 where the transfer head 11 transfers a paste adhesive stored in the second storage portion 25 and a substrate transfer position 33 where the transfer head 11 transfers the paste adhesives on to a substrate 8 are made to be situated on the same straight line in a first direction.

### BACKGROUND OF THE INVENTION

1. Field of the Invention

The present invention relates to an electronic component mounting apparatus in which a paste is transferred to a substrate by a transfer head and an electronic component is mounted on the substrate to which the paste has been transferred by a placement head.

2. Description of the Related Art

In the electronic components mounting field, there is a mounting method in which flux or paste such as an adhesive is transferred on to a substrate, so that an electronic component is placed on the portion of the substrate to which the adhesive has been transferred. Patent Document 1 discloses a mounting apparatus that realizing the mounting method described above. This mounting apparatus includes a plurality of paste storage portions (disks) for storing pastes which differ from each other in type and transfer thickness, so that a paste matching a type of an electronic component to be mounted can be transferred on to the substrate.

Patent Document 1: JP-A-2001-36223

In recent years, there have been demands for multi-bonders that handle many types of electronic components. Since the multi-bonder comes to use a plurality of pastes of different types, the multi-bonder needs to be provided with a plurality of storage portions. Because of this, in a related-art electronic component mounting apparatus like the one disclosed in Patent Document 1, as types of electronic components which are handled thereby increase, more places where to install storage portions come to be required, which has constituted a limitation on the miniaturization of such electronic component mounting apparatuses. In addition, in the event that the number of places where to install storage portions is increased, there are produced storage portions which have to be placed in positions which lie far away from a substrate, and as this occurs, the traveling time of a transfer head has to be prolonged, causing a problem that the production efficiency is reduced.

### SUMMARY OF THE INVENTION

The invention has been made in view of the situations described above, and an object thereof is to provide an electronic component mounting apparatus that realizes the miniaturization of the apparatus and increase in production efficiency thereof.

According to an aspect of the invention, there is provided an electronic component mounting apparatus including a paste storage portion, a transfer head for transferring a paste adhesive stored in the paste storage portion to a substrate, and a placement head for placing a picked-up electronic component on to the substrate to which the paste adhesive has been transferred, wherein the paste storage portion includes a plurality of storage portions which are formed between a plurality of concentric bulkheads having different diameters, and wherein a plurality of positions where the transfer head transfers paste adhesives from the individual storage portions and a position where the transfer head transfers the paste adhesives to the substrate are situated on the same straight line.

According to the aspect of the invention, since the plurality of storage portions are arranged in the concentric fashion and the plurality of positions where the paste adhesives are transferred from the respective storage portions and the position where the paste adhesives are transferred on to the substrate are set to be situated on the same straight line, a large area does not have to be required for installation of the plurality of storage portions, and the time necessary for the transfer head to travel can be reduced.

### BRIEF DESCRIPTION OF THE DRAWINGS

FIG. 1 is a diagram showing the configuration of an electronic component mounting apparatus of an embodiment of the invention.

FIG. 2 is a diagram showing a relationship between a plurality of positions where a transfer head of the embodiment of the invention implements transfers.

### DESCRIPTION OF THE PREFERRED EMBODIMENTS

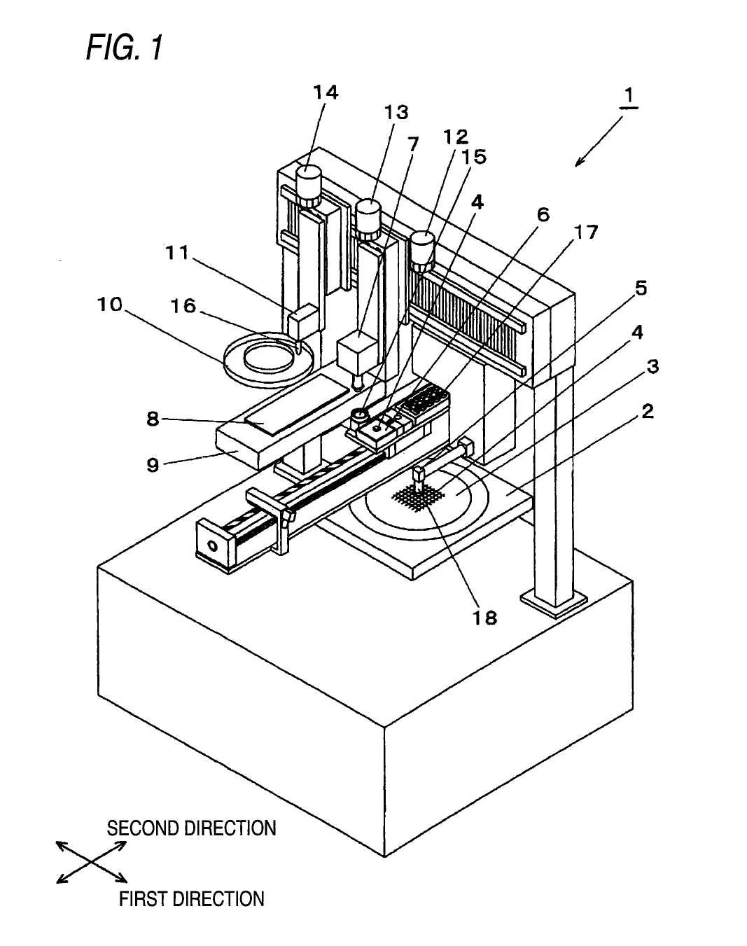

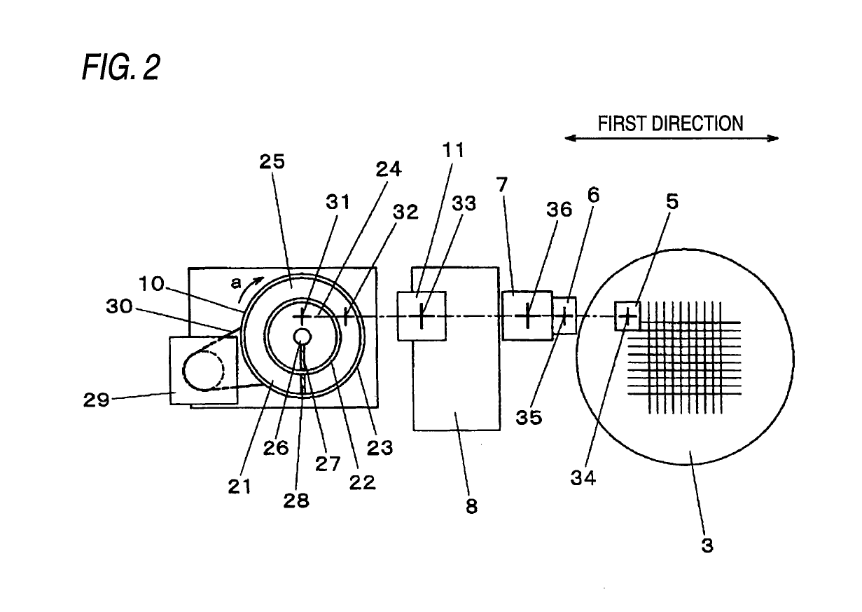

An embodiment of the invention will be described by reference to the drawings. FIG. 1 is a diagram showing the configuration of an electronic component mounting apparatus of the embodiment of the invention, and FIG. 2 is a diagram showing a relationship between a plurality of positions where a transfer head of the embodiment of the invention implements transfers.

Firstly, the configuration of an electronic component mounting apparatus will be described by reference to FIG. 1. An electronic component mounting apparatus 1 includes a wafer sheet holder 2, a pickup head 5 for picking up a chip 4 (an electronic component) from a wafer sheet 3 held by the wafer sheet holder 2, a chip relay table 6 where the chip 4 picked up from the wafer sheet 3 is placed temporarily, a mounting head 7 for receiving the chip 4 from the pickup head 5 or the chip relay table 6, a substrate support table 9 for supporting a substrate 8, a paste storage portion 10, a transfer head 11 for transferring paste adhesives stored in the paste storage portion 10 for supply to the substrate 8, a first camera 12 for verifying the position and orientation of the chip 4 bonded to the wafer sheet 3, a second camera 13 for verifying the position and orientation of the chip 4 which is placed temporarily on the chip relay table 6, a third camera 14 for verifying a paste adhesive application position which is set on the substrate 8, a fourth camera 15 for verifying the position and orientation of the chip 4 received by the mounting head 7, and a transfer tool replacement device 17 for accommodating transfer tools 16 which are to be attached to the transfer head 11.

The pickup head 5, the mounting head 7 and the transfer head 11 can each travel in a vertical direction and a horizontal direction (a first direction). The wafer sheet holder 2 and the substrate support table 9 can each travel in the first direction and a second direction which intersects the first direction at right angles within a horizontal plane. In addition, the chip relay table 6 and the transfer tool replacement device 17 can travel in the second direction. Further, the pickup head 5 can turn reversely about a horizontal axis so as to change the posture of a nozzle 18 to which the chip 4 is sucked to be oriented downwardly or upwardly.

The transfer tool replacement device 17 accommodates therein a plurality of transfer tools 16 of different types which correspond to types of chips, whereby when types of chips 4 are changed, the transfer head 11 travels as far as the transfer tool replacement device 17, so that a transfer tool 16 which is already attached to the transfer head 11 can be replaced with a required transfer tool 16.

Next, the configuration of the paste storage portion will be described by reference to FIG. 2. The paste storage portion 10 includes a circular bottom plate 21, and annular bulkheads 22, 23 that are centered at a center of the bottom plate 21. The bulkheads 22, 23 are arranged individually into concentric circles having different diameters. The inner bulkhead (inner wall) 22 and the outer bulkhead (outer wall) are each connected to the bottom plate 21 fluid-tightly, and insides and outsides of the bulkheads 22, 23 are separated thereby. An annular first storage portion 24 is formed inside the inner wall 22, and an annular second storage portion 25 is formed between the outer wall 23 and the inner wall 22. The first storage portion 24 and the second storage portion 25 store different types of paste adhesives. The paste storage portion 10 is pivotally supported by a pivot 26 at the center of the bottom plate 21, and when in use, the paste storage portion 10 is made to rotate about the pivot 26.

The first storage portion 24 and the second storage portion 25 individually include dams 27, 28 for adjusting levels of fluids stored therein. The levels of the paste adhesives stored downstream of the dams 27, 28 with respect to a rotational direction (a direction indicated by an arrow a) of the base storage portion 10 are adjusted so as to be the same in height as lower ends of the dams 27, 28. The dams 27, 28 can be adjusted in height independently of each other, and since the fluid level of the first storage portion and the fluid level of the second storage portion 25 can individually adjusted, thicknesses of the paste adhesives can be set to various film thicknesses which correspond to various types of chips 4. A motor 29 transmits its rotational driving force to the paste storage portion 10 by an endless belt 30.

Positions where the transfer head 11 transfers the paste adhesives are set in the base storage portion 10. These paste transfer positions are set one for each storage portion in such a manner as to correspond individually to the first storage portion 24 and the second storage portion 25. Specifically, there are set two transfer positions; a first transfer position 31 which corresponds to the first storage portion 24 and a second transfer position 32 which corresponds to the second storage portion 25. The first transfer position 31 and the second transfer position 32 are set in such a manner as to be situated on the same straight line on which a substrate transfer position 33 is situated where the transfer head 11 transfers the paste adhesives on to the substrate 8 in the first direction. Although the transfer head 11 travels to the first transfer position 31 or to the second transfer position 32 depending on the type of a chip 4 to be placed on the substrate 8, since the direction in which the transfer head 11 so travels is the first direction in either case, only traveling distances may be changed. In addition, since the annular first storage portion 24 and second storage portion 25 are concentrically disposed adjacent to each other, both the first transfer position 31 and the second transfer position can be set in positions which lie nearer to the substrate 8. Further, since a distance between the first transfer position 31 and the second transfer position 32 is extremely short, there is caused little difference in time required for the transfer head 11 to travel between the types of the paste adhesives that the transfer head 11 transfers.

The paste storage portion 10, the substrate 8, the chip relay table 6, and the wafer sheet 3 are arranged in that order from one side portion to the other side portion of the electronic component mounting apparatus 1. A position 34 where the pickup head 5 picks up a chip 4 from the wafer sheet 3, a position 35 where the pickup head 5 temporarily places the chip 4 with its face turned upwards on the chip relay table 6 and a position 36 where the pickup head 5 transfers to the mounting head 7 the chip 4 with its face turned downwards are also set in such a manner as to be situated on the same straight line on which the first transfer position 31 and the second transfer position 32 are situated in the first direction. Since the position where the mounting head 7 receives the chip from the pickup head 5 and the position 35 where the mounting head 7 receives the chip 4 from the chip relay table 6 are situated on the same straight line on which the position 33 where the transfer head 11 transfers the paste adhesives on to the substrate 8 is situated in the first direction, the chip 4 can be placed on the substrate 8 without moving the substrate 8 in the second direction.

Although the transfer tools 16 and film thicknesses of the paste adhesives have to be changed to match the type of a chip 4 to be used, in the electronic component mounting apparatus 10, since the transfer tools are made to be automatically changed for attachment to the transfer head 11 and the fluid levels of the paste adhesives are made to be adjusted freely, the electronic component mounting apparatus 10 can easily deal with a case where various types of chips 4 have to be handled.

The invention is useful for use in the field where electronic components are mounted on substrates to which paste adhesives are transferred.

What is claimed is:

1. An electronic component mounting apparatus, comprising:
a paste storage portion;
a transfer head transferring a paste adhesive stored in the paste storage portion to a substrate; and
a placement head placing a picked-up electronic component on onto the substrate to which the paste adhesive is transferred;
wherein the paste storage portion comprises a plurality of storage portions formed between a plurality of concentric bulkheads having different diameters, and
wherein a plurality of positions where the transfer head transfers paste adhesives from each of the storage portions and a position where the transfer head transfers the paste adhesives to the substrate are situated on the same straight line.
